(19) United States
(12) Patent Application Publication
(10) Pub. No.: US 2013/0012107 A1
(43) Pub. Date: Jan. 10, 2013

(54) LAMINATE POLISHING PAD

(75) Inventor: Atsushi Kazuno, Osaka-shi (JP)

(73) Assignee: TOYO TIRE & RUBBER CO., LTD., Osaka-shi, Osaka (JP)

(21) Appl. No.: 13/636,967

(22) PCT Filed: Mar. 11, 2011
(86) PCT No.: PCT/JP2011/055817

§ 371 Date: Sep. 24, 2012

(30) Foreign Application Priority Data
Mar. 25, 2010 (JP) 2010-070698
Oct. 28, 2010 (JP) 2010-242551
Mar. 1, 2011 (JP) 2011-044192

(51) Int. Cl. B24D 11/00; H01L 21/304

(52) U.S. Cl. 451/41; 451/534

(57) ABSTRACT

An object of the invention is to provide a laminate polishing pad having a polishing layer and a cushion layer, which resist peeling. A laminate polishing pad including: a polishing layer with no region passing therethrough; an adhesive member; and a cushion layer placed on the polishing layer with the adhesive member interposed therebetween, wherein the back side of the polishing layer has at least one non-adhering region X continuously extending from a central region of the polishing layer to a peripheral end of the polishing layer, and/or the adhesive member has at least one non-adhering region Y continuously extending from a central region of the adhesive member to a peripheral end of the adhesive member.

### REFERENCE TO RELATED APPLICATIONS

This application is a national stage application under 35 USC 371 of International Application No. PCT/JP2011/055817, filed Mar. 11, 2011, which claims the priority of Japanese Patent Application No. 2010-070698, filed Mar. 25, 2010, Japanese Patent Application No. 2010-242551, filed Oct. 28, 2010, and Japanese Patent Application No. 2011-044192, filed Mar. 1, 2011, the entire contents of which are incorporated herein by reference.

### FIELD OF THE INVENTION

The present invention relates to a laminate polishing pad by which the planarizing processing of optical materials such as lenses, reflecting mirrors and the like, silicon wafers, glass substrates for hard disks, aluminum substrates, and materials requiring a high degree of surface planarity such as those in general metal polishing processing can be carried out stably with high polishing efficiency. The laminate polishing pad of the present invention is used particularly preferably in a process of planarizing a silicone wafer, and a device having an oxide layer, a metal layer or the like formed on a silicon wafer, before lamination and formation of the oxide layer, the metal layer or the like.

### BACKGROUND OF THE INVENTION

Production of a semiconductor device involves a step of forming an electroconductive film on the surface of a wafer to form a wiring layer by photolithography, etching etc., a step of forming an interlaminar insulating film on the wiring layer, etc., and an uneven surface made of an electroconductive material such as metal and an insulating material is generated on the surface of a wafer by these steps. In recent years, processing for fine wiring and multilayer wiring is advancing for the purpose of higher integration of semiconductor integrated circuits, and accordingly techniques of planarizing an uneven surface of a wafer have become important.

As the method of planarizing an uneven surface of a wafer, a CMP method is generally used. CMP is a technique wherein while the surface of a wafer to be polished is pressed against a polishing surface of a polishing pad, the surface of the wafer is polished with slurry having abrasive grains dispersed therein. As shown in FIG. 1, a polishing apparatus used generally in CMP is provided for example with a polishing platen 2 for supporting a polishing pad 1, a supporting stand (polishing head) 5 for supporting a polished material (wafer) 4, a backing material for uniformly pressurizing a wafer, and a mechanism of feeding an abrasive. The polishing pad 1 is fitted with the polishing platen 2 for example via a double-sided tape. The polishing platen 2 and the supporting stand 5 are provided with rotating shafts 6 and 7 respectively and are arranged such that the polishing pad 1 and the polished material 4, both of which are supported by them, are opposed to each other. The supporting stand 5 is provided with a pressurizing mechanism for pushing the polished material 4 against the polishing pad 1.

Conventional polishing pads for use in high-precision polishing are generally produced using a polyurethane foam sheet. Unfortunately, such a polyurethane foam sheet has insufficient cushioning properties and therefore can hardly apply uniform pressure to the entire surface of a wafer, though it has high local-planarization performance. In general, therefore, a soft cushion layer is additionally provided on the backside of such a polyurethane foam sheet, and the resulting laminate polishing pad is used for polishing.

Unfortunately, conventional laminate polishing pads, which have layers bonded together with an adhesive or a pressure-sensitive adhesive, have a problem in which peeling or displacement is more likely to occur between the layers during polishing.

For example, to prevent peeling of the central region of an upper layer from an intermediate layer even when stress is applied from a dresser or any other tool reciprocating in the diametrical direction, there is proposed a chemical mechanical polishing (CMP) pad including: an upper layer made of a polishing material as a single uniform layer; an intermediate layer that is for blocking penetration of a slurry and has an upper surface bonded to the upper layer with an adhesive; and a lower layer that possesses cushion properties and has an upper surface bonded to the intermediate layer with an adhesive, wherein the intermediate layer and the lower layer are fixed to each other at a circumference region but not fixed at a central region (Patent Document 1).

To prevent irregularities caused by folding when a shearing force is applied between a tape and a polishing layer to cause lateral slip, which cannot be absorbed at the central part of the polishing layer, there is proposed a polishing pad including a polishing layer having a circular slit and/or a circular hole, which has a diameter equal to 3 to 30% of the diameter of the polishing pad and is concentric with the polishing pad (Patent Document 2).

To prevent peeling between a polishing layer and a backing layer, there is proposed a polishing pad including a polishing layer, a backing layer that supports the polishing layer, and a pressure-sensitive adhesive layer with which the polishing layer and the backing layer are bonded together, wherein the polishing layer has a through hole formed at a central part, and the pressure-sensitive adhesive layer is placed on a whole circumference region of the polishing layer (Patent Document 3).

To prevent peeling between a polishing layer and a backing layer, there is proposed a polishing pad including a polishing layer, a backing layer that supports the polishing layer, and a pressure-sensitive adhesive layer with which the polishing layer and the backing layer are bonded together, wherein the polishing layer has a first through hole formed at a central part, the backing layer has a second through hole formed at a central part, and the pressure-sensitive adhesive layer is placed on a whole circumference region of the polishing layer (Patent Document 4).

To prevent a polishing layer from peeling from a supporting plate when a slurry affects an adhesive layer, there is proposed a polishing pad including: a disc-shaped polishing layer having a plurality of through holes formed from the front surface to the back surface; an adhesive layer provided only on a part of the back surface of the polishing layer, wherein the part does not have the through holes; and a disc-shaped supporting plate having a flat surface bonded to the back surface of the polishing layer with the adhesive layer (Patent Document 5).

If gas is produced by a reaction between a slurry and a pressure-sensitive adhesive layer, a polishing layer may peel from a backing layer, and bulging may occur on the circumference of an end-point-detection window of the polishing layer. In order to prevent that, there is proposed a polishing pad having a two-layer structure including a backing layer to be bonded to a platen and a polishing layer bonded to the upper side of the backing layer, wherein a gas-discharge path communicating with the outside is formed in part of the backing layer (Patent Document 6).

To solve a problem in which a slurry stays in an optical detection through-hole to make it difficult for light to pass through it sufficiently or to solve a problem in which polishing dust stays to cause scratches, there is proposed a polishing pad including a polishing layer, a through hole passing between the polishing surface and the back surface, and a path passing between the through hole and the side surface of the polishing pad (Patent Document 7).

To make it easy to remove a semiconductor wafer after the completion of polishing, to reduce the necessary amount of a polishing agent, and to reduce degradation over time, there is proposed a polishing pad having: a large number of holes for holding a polishing agent; and a groove formed on the side opposite to the side for polishing an object (Patent Document 8).

There is also proposed a polishing pad that has a groove formed on the back side so that the time for replacement of the pad can be identified when the groove is exposed by abrasion of the pad during polishing (Patent Document 9).

To stabilize polishing rate and maintain uniformity and flatness, there is proposed a polishing pad having grooves formed on both of the surface for polishing an object and the opposite surface (Patent Document 10).

To make it possible to suppress the occurrence of scratches on an object being polished and to provide a polished surface with high surface flatness, there is proposed a polishing pad having a surface for polishing an object, a non-polishing surface opposite to the polishing surface, and a side surface connecting both of these surfaces, the polishing pad also having a recessed pattern on the non-polishing surface, wherein the recessed pattern has an opening on the non-polishing surface but does not have any opening on the side surface (Patent Document 11).

Unfortunately, the problem that peeling is more likely to occur between a cushion layer and a polishing layer with no through hole has not been solved fully.
Patent Document 1: JP-A-2008-53376
Patent Document 2: JP-A-2008-229807
Patent Document 3: JP-A-2007-319979
Patent Document 4: JP-A-2007-319980
Patent Document 5: JP-A-2007-266052
Patent Document 6: JP-A-2009-269103
Patent Document 7: JP-A-2007-105836
Patent Document 8: JP-A-09-117855
Patent Document 9: JP-A-10-100062
Patent Document 10: JP-A-2002-192455
Patent Document 11: JP-A-2005-159340

### SUMMARY OF THE INVENTION

An object of the invention is to provide a laminate polishing pad having a polishing layer and a cushion layer, which resist peeling.

As a result of investigations for solving the problems described above, the inventors have found that the objects can be achieved by the laminate polishing pad described below, and have completed the invention.

Thus, the invention is directed to a laminate polishing pad including: a polishing layer with no region passing therethrough; an adhesive member; and a cushion layer placed on the polishing layer with the adhesive member interposed therebetween, wherein the back side of the polishing layer has at least one non-adhering region X continuously extending from a central region of the polishing layer to a peripheral end of the polishing layer, and/or the adhesive member has at least one non-adhering region Y continuously extending from a central region of the adhesive member to a peripheral end of the adhesive member.

It is considered that during polishing, a slurry supplied to the surface of a polishing layer can penetrate the polishing layer to reach a lower adhesive layer. It is also considered that during polishing, the temperature of a polishing pad can rise to about 50-70° C. due to the friction between the polishing layer and a wafer, so that not only the adhering strength of the adhesive layer can be reduced by heat, but also a chemical reaction can occur between the slurry and the adhesive layer to produce gas inside the polishing pad, or the solvent in the adhesive layer can be gasified by heat. It is considered that when there is no path for allowing gas to escape to the outside, the gas produced inside the polishing pad can stay between the polishing layer and the adhesive layer, so that peeling or gas blistering may be more likely to occur between the polishing layer and the adhesive layer.

The inventors have found that when the back side of a polishing layer has at least one non-adhering region X continuously extending from a central region of the polishing layer to a peripheral end of the polishing layer and/or when an adhesive member has at least one non-adhering region Y continuously extending from a central region of the adhesive member to a peripheral end of the adhesive member as stated above, gas produced inside the polishing pad can be discharged to the outside through the non-adhering region, so that peeling or gas blistering can be effectively prevented between the polishing layer and the adhesive member.

The adhesive member may be an adhesive layer having the non-adhering region Y or include a base film and adhesive layers provided on both sides of the base film, in which the polishing layer-side adhesive layer may have the non-adhering region Y. The latter is preferably used to prevent a slurry from penetrating to the cushion layer side and to prevent peeling between the cushion layer and the adhesive layer.

The non-adhering region X or Y is preferably formed radially or in a lattice pattern. Gas produced inside the polishing pad can be efficiently discharged to the outside through the non-adhering region formed radially or in a lattice pattern, so that peeling or gas blistering can be prevented over the pad.

The non-adhering region X or Y preferably has a total surface area equal to 0.1 to 30% of the surface area of the polishing layer. If the total surface area is less than 0.1%, it may be difficult to discharge, to the outside, gas produced in a wide area of the polishing pad, so that the gas may be more likely to stay locally between the polishing layer and the adhesive member. As a result, peeling or gas blistering may occur locally between the polishing layer and the adhesive member, which may reduce the flatness of the polishing layer, so that polishing characteristics such as planarization characteristics may tend to decrease. On the other hand, if the total surface area is more than 30%, the contact area between the polishing layer and the adhesive member may be so small that peeling may tend to occur easily between the polishing layer and the adhesive member.

Also, the invention relates to a method for manufacturing a semiconductor device, comprising a step of polishing a surface of a semiconductor wafer using the aforementioned polishing pad.

In the laminate polishing pad of the invention, the back side of the polishing layer has the non-adhering region X continuously extending from a central region of the polishing layer to a peripheral end of the polishing layer, and/or the adhesive member has the non-adhering region Y continuously extending from a central region of the adhesive member to a peripheral end of the adhesive member. Therefore, gas produced inside the polishing pad can be efficiently discharged to the outside through the non-adhering region, so that peeling or gas blistering can be effectively prevented between the polishing layer and the adhesive member.

### BRIEF DESCRIPTION OF THE DRAWINGS

FIG. 1 is a schematic diagram showing an exemplary polishing apparatus used in CMP.

FIG. 2 is a schematic cross-sectional view showing a structure of the laminate polishing pad of the invention.

FIG. 3 is a schematic diagram showing an example of the structure of the non-adhering region X formed in the back side of the polishing layer.

FIG. 4 is a schematic diagram showing an another example of the structure of the non-adhering region X formed in the back side of the polishing layer.

FIG. 5 is a schematic diagram showing an another example of the structure of the non-adhering region X formed in the back side of the polishing layer.

FIG. 6 is a schematic diagram showing an another example of the structure of the non-adhering region X formed in the back side of the polishing layer.

FIG. 7 is a schematic diagram showing an another example of the structure of the non-adhering region X formed in the back side of the polishing layer.

FIG. 8 is a schematic diagram showing an another example of the structure of the non-adhering region X formed in the back side of the polishing layer.

FIG. 9 is a schematic diagram showing an another example of the structure of the non-adhering region X formed in the back side of the polishing layer.

FIG. 10 is a schematic cross-sectional view showing an another structure of the laminate polishing pad of the invention.

FIG. 11 is a schematic cross-sectional view showing an another structure of the laminate polishing pad of the invention.

### DETAILED DESCRIPTION OF THE INVENTION

In the invention, the polishing layer may be of any type as long as it has no region passing therethrough and includes a foam having fine cells. For example, the material may be one or a mixture of two or more of polyurethane resin, polyester resin, polyamide resin, acrylic resin, polycarbonate resin, halogen-containing resin (e.g., polyvinyl chloride, polytetrafluoroethylene, or polyvinylidene fluoride), polystyrene, olefin resin (e.g., polyethylene or polypropylene), epoxy resin, photosensitive resin, and others. Polyurethane resin is a particularly preferred material for forming the polishing layer because it has high abrasion resistance and because urethane polymers with the desired physical properties can be easily obtained by varying the raw material composition. Hereinafter, a description is given on polyurethane resin as a typical material for forming the polishing layer.

The polyurethane resin is constituted of an isocyanate component, a polyol component (a high-molecular-weight polyol, a low-molecular-weight polyol and the like) and a chain extender.

As the isocyanate component, a compound known in the field of polyurethane can be used without particular limitation. The isocyanate component includes, for example, aromatic diisocyanates such as 2,4-toluene diisocyanate, 2,6-toluene diisocyanate, 2,2′-diphenyl methane diisocyanate, 2,4′-diphenyl methane diisocyanate, 4,4′-diphenyl methane diisocyanate, 1,5-naphthalene diisocyanate, p-phenylene diisocyanate, m-phenylene diisocyanate, p-xylylene diisocyanate and m-xylylene diisocyanate, aliphatic diisocyanates such as ethylene diisocyanate, 2,2,4-trimethyl hexamethylene diisocyanate and 1,6-hexamethylene diisocyanate, and cycloaliphatic diisocyanates such as 1,4-cyclohexane diisocyanate, 4,4′-dicyclohexyl methane diisocyanate, isophorone diisocyanate and norbornane diisocyanate. These may be used alone or as a mixture of two or more thereof.

As the isocyanate component, it is possible to use not only the above-described diisocyanate compounds but also multifunctional (trifunctional or more) polyisocyanates. As the multifunctional isocyanate compounds, a series of diisocyanate adduct compounds are commercially available as Desmodul-N (Bayer) and Duranate™ (Asahi Chemical Industry Co., Ltd.).

As the high-molecular-weight polyol, a compound known in the field of polyurethane can be used without particular limitation. The high-molecular-weight polyol includes, for example, polyether polyols represented by polytetramethylene ether glycol and polyethylene glycol, polyester polyols represented by polybutylene adipate, polyester polycarbonate polyols exemplified by reaction products of polyester glycols such as polycaprolactone polyol and polycaprolactone with alkylene carbonate, polyester polycarbonate polyols obtained by reacting ethylene carbonate with a multivalent alcohol and reacting the resulting reaction mixture with an organic dicarboxylic acid, and polycarbonate polyols obtained by ester exchange reaction of a polyhydroxyl compound with aryl carbonate. These may be used singly or as a mixture of two or more thereof.

No limitation is imposed on a number-average molecular weight of a high-molecular-weight polyol but it is preferably in the range of from 500 to 2000 from the viewpoint of an elastic characteristic of an obtained polyurethane resin. If a number-average molecular weight thereof is less than 500, a polyurethane resin obtained by using the polyol does not have a sufficient elastic characteristic and easy to be fragile, and a polishing pad made from the polyurethane resin is excessively hard, which sometimes causes scratches to be generated on a surface of an object to be polished. Moreover, since a polishing pad is easy to be worn away, it is unpreferable from the viewpoint of a life of a polishing pad. On the other hand, if a number-average molecular weight thereof exceeds 2000, a polishing pad made from a polyurethane resin obtained from such a polyol is unpreferably soft to thereby disable a sufficiently satisfiable planarity to be earned.

Besides the above high-molecular-weight polyol described in the above as a polyol component, it is preferred to concomitantly use a low-molecular-weight polyol such as ethyleneglycol, 1,2-propylene glycol, 1,3-propylene glycol, 1,4-butanediol, 1,6-hexanediol, neopentylglyol, 1,4-cyclohexanedimethanol, 3-methyl-1,5-pentanediol, diethyleneglycol, triethyleneglycol, and 1,4-bis(2-hydroxyethoxy)benzene. Low-molecular-weight polyamine such as ethylenediamine, tolylenediamine, diphenylmethanediamine, and diethylenetriamine may be used. These may be used singly or in combination of two or more kinds.

The ratio of the amounts of the high-molecular-weight polyol, the low-molecular-weight polyol and the low-molecular-weight polyamine in the polyol components may be determined depending on the desired characteristics of the polishing layer to be produced with the polyols.

In the case where a polyurethane foam is produced by means of a prepolymer method, a chain extender is used in curing of a prepolymer. A chain extender is an organic compound having at least two active hydrogen groups and examples of the active hydrogen group include: a hydroxyl group, a primary or secondary amino group, a thiol group (SH) and the like. Concrete examples of the chain extender include: polyamines such as 4,4′-methylenebis(o-chloroaniline) (MOCA), 2,6-dichloro-p-phenylenediamine, 4,4′-methylenebis(2,3-dichloroaniline), 3,5-bis(methylthio)-2,4-toluenediamine, 3,5-bis(methylthio)-2,6-toluenediamine, 3,5-diethyltoluene-2,4-diamine, 3,5-diethyltoluene-2,6-diamine, trimethylene glycol-di-p-aminobenzoate, polytetramethylene oxide-di-p-aminobenzoate, 4,4′-diamino-3,3′,5,5′-tetraethyldiphenylmethane, 4,4′-diamino-3,3′-diisopropyl-5,5′-dimethyldiphenylmethane, 4,4′-diamino-3,3′,5,5′-tetraisopropyldiphenylmethane, 1,2-bis(2-aminophenylthio)ethane, 4,4′-diamino-3,3′-diethyl-5,5′-dimethyldiphenylmethane, N,N′-di-sec-butyl-4,4′-diaminophenylmethane, 3,3′-diethyl-4,4′-diaminodiphenylmethane, m-xylylenediamine, N,N′-di-sec-butyl-p-phenylenediamine, m-phenylenediamine and p-xylylenediamine; low-moleculer-weight polyol component; and a low-molecular-weight polyamine component. The chain extenders described above may be used either alone or in mixture of two kinds or more.

A ratio between an isocyanate component, a polyol component and a chain extender in the invention can be altered in various ways according to molecular weights thereof, desired physical properties of polyurethane foam and the like. In order to obtain polyurethane foam with desired polishing characteristics, a ratio of the number of isocyanate groups in an isocyanate component relative to a total number of active hydrogen groups (hydroxyl groups+amino groups) in a polyol component and a chain extender is preferably in the range of from 0.80 to 1.20 and more preferably in the range of from 0.99 to 1.15. When the number of isocyanate groups is outside the aforementioned range, there is a tendency that curing deficiency is caused, required specific gravity and hardness are not obtained, and polishing property is deteriorated.

A polyurethane foam can be produced by applying a melting method, a solution method or a known polymerization technique, among which preferable is a melting method, consideration being given to a cost, a working environment and the like.

Manufacture of a polyurethane foam is enabled by means of either a prepolymer method or a one shot method, of which preferable is a prepolymer method in which an isocyanate-terminated prepolymer is synthesized from an isocyanate component and a polyol component in advance, with which a chain extender is reacted since physical properties of an obtained polyurethane resin is excellent.

Note that an isocyanate-terminated prepolymer with a molecular weight of the order in the range of from 800 to 5000 is preferable because of excellency in workability and physical properties.

Manufacture of the polyurethane foam is to mix the first component containing an isocyanate group containing compound and the second component containing an active hydrogen group containing compound to thereby cure the reaction product. In the prepolymer method, an isocyanate-terminated prepolymer serves as an isocyanate group containing compound and a chain extender serves as an active hydrogen group containing compound. In the one shot method, an isocyanate component serves as an isocyanate group containing compound, and a chain extender and a polyol component combined serves as an active hydrogen containing compound.

Manufacturing methods of a polyurethane foam include: a method in which hollow beads are added, a mechanical foaming method, a chemical foaming method and the like.

Particularly, preferred is a mechanical foaming method using a silicone-based surfactant which is a copolymer of polyalkylsiloxane and polyether and has no an active hydrogen group. Preferred examples of such a silicone-based surfactant include SH-192, SH-193 (manufactured by Dow Corning Toray Silicone Co., Ltd.) and L5340 (manufactured by Nippon Unicar Co., Ltd).

A stabilizer such as antioxidant, a lubricant, a pigment, a filler, an antistatic agent and other additives may be added, as needed.

The polyurethane foam as a material for forming the polishing layer may be of a closed-cell type or an open-cell type. Hereinafter, a description is given of examples of the method of producing a closed-cell type polyurethane foam. When a closed-cell type is used, penetration of a slurry can be suppressed. A method of manufacturing such a polyurethane foam has the following steps:

1) a foaming step of preparing a bubble dispersion liquid of an isocyanate-terminated prepolymer (first component),
wherein a silicone-based surfactant is added into an isocyanate-terminated prepolymer, which is agitated in the presence of a non-reactive gas to thereby disperse the non-reactive gas into the prepolymer as fine bubbles and obtain a bubble dispersion liquid. In a case where the prepolymer is solid at an ordinary temperature, the prepolymer is preheated to a porper temperature and used in a molten state.
2) a curing agent (chain extender) mixing step,
wherein a chain extender (second component) is added into the bubble dispersion liquid, which is agitated to thereby obtain a foaming reaction liquid.
3) a casting step,
wherein the forming reaction liquid is cast into a mold.
4) a curing step,
wherein the foaming reaction liquid having been cast into the mold is heated and reaction-cured.

The non-reactive gas used for forming fine bubbles is preferably not combustible, and is specifically nitrogen, oxygen, a carbon dioxide gas, a rare gas such as helium and argon, and a mixed gas thereof, and the air dried to remove water is most preferable in respect of cost.

As a stirrer for dispersing the silicone-based surfactant-containing first component to form fine bubbles with the non-reactive gas, known stirrers can be used without particular limitation, and examples thereof include a homogenizer, a dissolver, a twin-screw planetary mixer etc. The shape of a stirring blade of the stirrer is not particularly limited either, but a whipper-type stirring blade is preferably used to form fine bubbles.

In a preferable mode, different stirrers are used in stirring for forming a bubble dispersion liquid in the stirring step and in stirring for mixing an added chain extender in the mixing step, respectively. In particular, stirring in the mixing step may not be stirring for forming bubbles, and a stirrer not generating large bubbles is preferably used. Such a stirrer is preferably a planetary mixer. The same stirrer may be used in the stirring step and the mixing step, and stirring conditions such as revolution rate of the stirring blade are preferably regulated as necessary.

In the method of producing the polyurethane foam with fine cells, heating and post-curing of the foam obtained after casting and reacting the forming reaction liquid in a mold until the dispersion lost fluidity are effective in improving the physical properties of the foam, and are extremely preferable. The forming reaction liquid may be cast in a mold and immediately post-cured in a heating oven, and even under such conditions, heat is not immediately conducted to the reactive components, and thus the diameters of cells are not increased. The curing reaction is conducted preferably at normal pressures to stabilize the shape of cells.

In the production of the polyurethane foam, a known catalyst promoting polyurethane reaction, such as tertiary amine-based catalysts, may be used. The type and amount of the catalyst added are determined in consideration of flow time in casting in a predetermined mold after the mixing step.

Production of the polyurethane foam may be in a batch system where each component is weighed out, introduced into a vessel and mixed or in a continuous production system where each component and a non-reactive gas are continuously supplied to, and stirred in, a stirring apparatus and the resulting forming reaction liquid is transfered to produce molded articles.

A manufacturing method of a polyurethane foam may be performed in ways: in one of which a prepolymer which is a raw material from which a polyurethane foam is made is put into a reactor, thereafter a chain extender is mixed into the prepolymer, the mixtue is agitated, thereafter the mixture is cast into a mold with a predetermined size to thereby prepare a block and the block is sliced with a slicer like a planer or a band saw; and in another of which in the step of casting into the mold, a thin sheet may be directly produced. Besides, a still another way may be adopted in which a resin of raw material is melted, the melt is extruded through a T die to thereby mold a polyurethane foam directly in the shape of a sheet.

An average cell diameter of a polyurethane foam is preferably in the range of from 30 to 80 μm and more preferably in the range of from 30 to 60 μm. If an average cell diameter falls outside the range, a tendency arises that a polishing rate is decreased and a planarity of an object to be polished (a wafer) after polishing is reduced.

Preferably, the polyurethane foam has a specific gravity ranging from 0.5 to 1.3. When the specific gravity is less than 0.5, the surface strength of the polishing layer decreases, so that the planarity of the object to be polished tends to decrease. When the specific gravity is larger than 1.3, the cell number on the surface of the polishing layer decreases, so that the polishing rate tends to decrease despite excellent planarity.

Preferably, the polyurethane foam has a hardness measured by ASKER D hardness meter, ranging from 45 to 70 degrees. When the ASKER D hardness is less than 45 degrees, the planarity of the object to be polished decreases, while when the hardness is more than 70 degrees, the uniformity of the object to be polished tends to decrease despite excellent planarity.

A polishing surface of the polishing layer, which comes into contact with an object to be polished may have a asperity structure (but except a penetration structure) provided for retaining and refreshing a slurry. A polishing layer made of a foam has a number of openings in the polishing surface, and has a function of retaining and refreshing a slurry. By forming an asperity structure on the polishing surface, it is possible to conduct retention and refreshment of the slurry more efficiently, and to prevent the object to be polished from breaking due to adsorption of the material to be polished. The shape of the asperity structure is not particularly limited insofar as it is not a penetration structure and it is able to retain and refresh a slurry, and for example, XY grating groove, concentric ring groove, polygonal column, circular cylinder, spiral groove, eccentric ring groove, radial groove, and combination thereof can be recited. These asperity structures generally have regularity, however, groove pitch, groove width, groove depth and the like may be varied by a certain range for achieving desired retention and refreshment of slurry.

A preparation method of the asperity structure is not particularly limited. Examples of preparation method include the method of machine cutting using a jig such as a bite of predetermined size, the preparation method of pouring a resin into a mold having a predetermined surface shape, and allowing the resin to harden, the preparation method of pressing a resin with a pressing plate having a predetermined surface shape, the preparation method of using photolithography, the preparation method using printing techniques, and the preparation method based on laser beam using carbon dioxide gas laser or the like.

The polishing layer may have any shape such as a circular shape or an elongated shape. The size of the polishing layer may be appropriately adjusted depending on the polishing apparatus to be used. When the polishing layer is circular, it may have a diameter of about 30 to about 150 cm, and when the polishing layer has an elongated shape, it may have a length of about 5 to about 15 m and a width of about 60 to about 250 cm.

The thickness of the polishing layer is preferably from 0.3 to 2 mm, while it may be adjusted as needed in view of the relationship with a cushion layer or polishing characteristics. The method of preparing the polishing layer of this thickness includes a method wherein a block of the fine-cell foam is cut in predetermined thickness by a slicer in a bandsaw system or a planing system, a method that involves casting resin into a mold having a cavity of predetermined thickness and curing the resin, a method of using coating techniques and sheet molding techniques, etc.

The polishing layer may also have a light-transmitting region for use in detecting an optical end point while polishing is performed.

A cushion layer compensates for characteristics of the polishing layer. The cushion layer is required for satisfying both planarity and uniformity which are in a tradeoff relationship in CMP. Planarity refers to flatness of a pattern region upon polishing an object to be polished having fine unevenness generated upon pattern formation, and uniformity refers to the uniformity of the whole of an object to be polished. Planarity is improved by the characteristics of the polishing layer, while uniformity is improved by the characteristics of the cushion layer. The cushion layer used in the laminate polishing pad of the present invention is preferably softer than the polishing layer.

The material for forming the cushion layer is not particularly limited as long as it is softer than the polishing layer. Examples of such material include a nonwoven fabric such as a polyester nonwoven fabric, a nylon nonwoven fabric or an acrylic nonwoven fabric, a nonwoven fabric impregnated with resin such as a polyester nonwoven fabric impregnated with polyurethane, polymer resin foam such as polyurethane foam and polyethylene foam, rubber resin such as butadiene rubber and isoprene rubber, and photosensitive resin.

In view of the relationship with the polishing layer or polishing characteristics, the thickness of the cushion layer is preferably from 0.5 to 2 mm, more preferably from 0.8 to 1.5 mm.

When a light-transmitting region is formed in the polishing layer, a through hole for transmitting light is preferably formed in the cushion layer.

FIG. 2 is a schematic cross-sectional view showing the structure of a laminate polishing pad according to the invention. A laminate polishing pad 1 according to the invention has a structure including a polishing layer 8 with no region passing therethrough and a cushion layer 10, which are laminated with an adhesive layer 9a interposed therebetween. The back side of the polishing layer 8 has at least one non-adhering region X (11) continuously extending from a central region 12 of the polishing layer 8 to a peripheral end of the polishing layer 8.

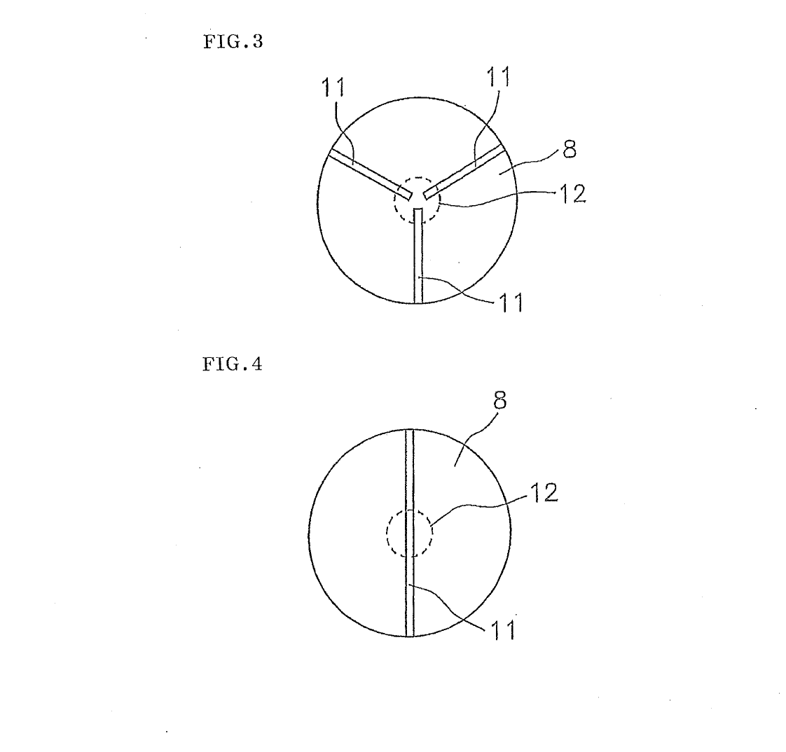

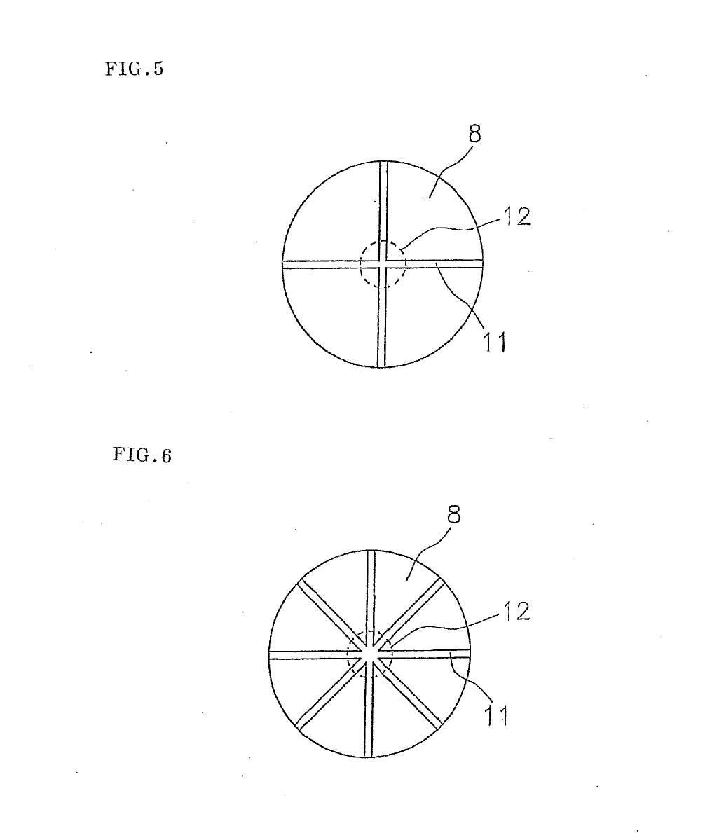

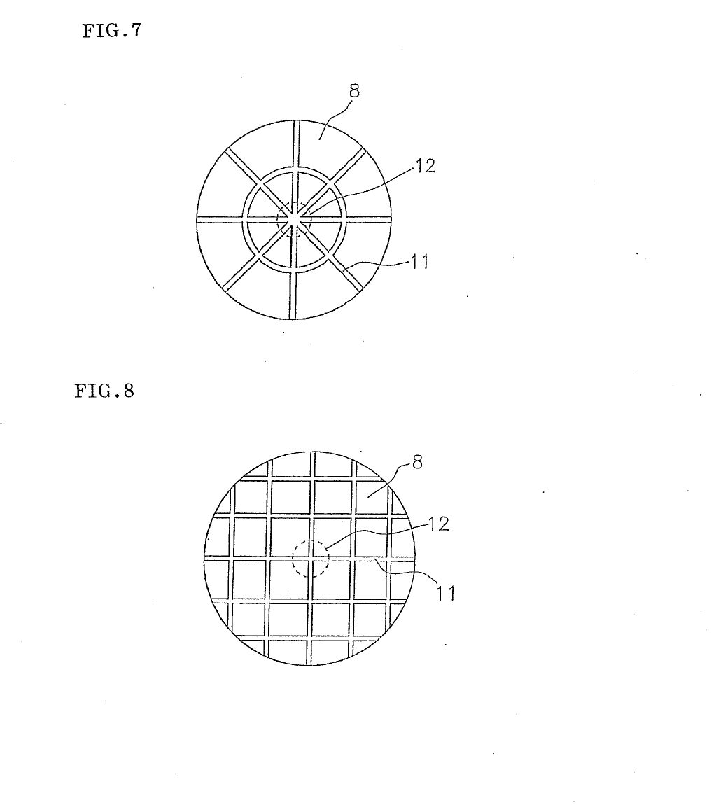

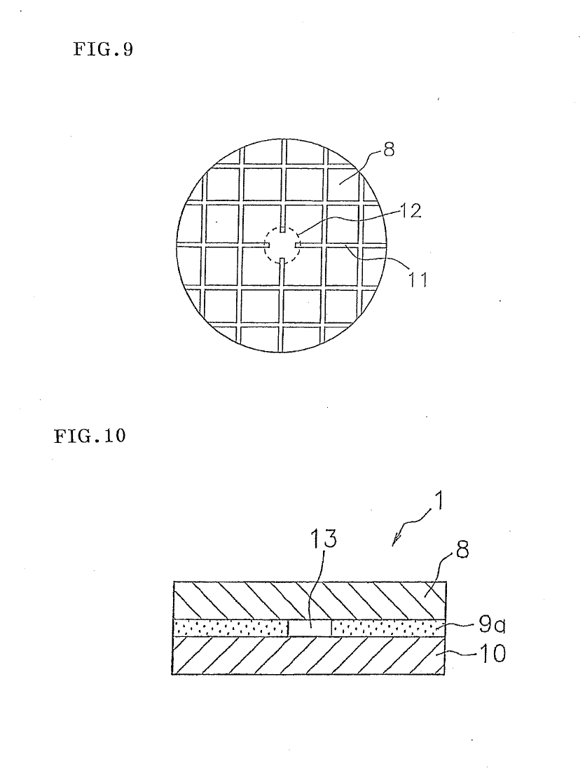

FIGS. 3 to 9 are schematic diagrams showing structures of the non-adhering region X of the back side of the polishing layer. The non-adhering region X (11) may have any shape as long as it is at least formed continuously from the central region 12 to the peripheral end of the polishing layer 8, and it may have a linear shape, a curved shape, or a combination thereof. For example, as shown in FIGS. 3 and 9, the non-adhering region X (11) may be interrupted at the central region 12, or as shown in FIGS. 4 to 8, the non-adhering region X (11) may be continuous at the central region 12. As shown in FIG. 6, it is preferred that the non-adhering region X (11) be radially formed, and as shown in FIG. 7, the non-adhering region X (11) may be in a combination of radial and concentric patterns. As shown in FIGS. 8 and 9, the non-adhering region X (11) may also be lattice-shaped. In the case of a lattice shape, the groove pitch is preferably from 30 to 150 mm, more preferably from 45 to 100 mm. If the groove pitch is less than 30 mm, the total area of adhesion between the polishing layer and the adhesive layer may be so small that peeling may be more likely to occur between the polishing layer and the adhesive layer. If the groove pitch is more than 150 mm, peeling or gas blistering may be more likely to occur locally between the polishing layer and the adhesive layer.

The non-adhering region X (11) should be a groove or grooves not passing through the polishing layer to its surface side. The width of the groove, which may be adjusted as needed depending on the size of the polishing layer, is generally from about 0.1 to about 10 mm, preferably from 0.5 to 3 mm. The depth of the groove, which may be adjusted as needed depending on the thickness of the polishing layer, is generally from about 0.05 to about 0.5 mm, preferably from 0.1 to 0.3 mm. The pitch, width, and depth of the groove may vary from one area to another.

In the case of a circular polishing layer, the central region 12 may be a 3 cm radius region from the center, and in the case of an elongated polishing layer, the central region 12 may be a region from the center to the left and right edges each 3 cm apart in the width direction.

Examples of the method of forming the non-adhering region X (11) include, but are not limited to, a mechanical cutting method using a tool such as a cutting tool of a specific size, a method including pouring resin into a mold with a specific surface pattern and curing the resin to form the region, a method of pressing resin with a pressing plate having a specific surface pattern to form the region, a method using photolithography to form the region, a method using a printing technique to form the region, and a method of performing decomposition and removal using a beam from a laser such as a carbon dioxide laser to form the region.

The total surface area of the non-adhering region X (11) is preferably from 0.1 to 30%, more preferably from 0.5 to 10% of the surface area of the polishing layer.

Examples of the material used to form the adhesive layer 9a include, but are not limited to, a rubber-based adhesive, an acrylic adhesive, and a hot melt adhesive. The thickness of the adhesive layer 9a is preferably, but not limited to, 10 to 200 μm, more preferably 40 to 150 μm in view of adhering strength and shearing stress.

For example, the method of bonding the polishing layer and the cushion layer together may be, but not limited to, a method including transferring the adhesive layer, which is formed on a release sheet, from the release sheet onto the cushion layer, then placing the polishing layer on the adhesive layer, and pressing the resulting laminate.

A double-sided adhesive tape including a base film and adhesive layers provided on both sides of the base film may also be used in place of the adhesive layer 9a. The base film can prevent penetration of a slurry to the cushion layer side and also prevent peeling or gas blistering between the cushion layer and the adhesive layer.

Examples of the base film include polyester films such as polyethylene terephthalate films and polyethylene naphthalate films; polyolefin films such as polyethylene films and polypropylene films; and nylon films. Among them, polyester films are preferably used because their property of preventing water penetration is high.

The thickness of the base film is preferably, but not limited to, 5 to 200 μm, more preferably 15 to 50 μm in view of flexibility and rigidity.

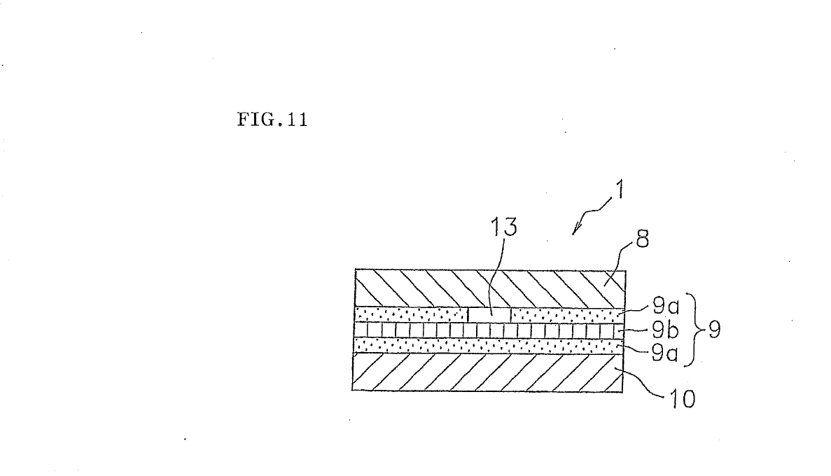

On the other hand, FIG. 10 is a schematic cross-sectional view showing another structure of the laminate polishing pad of the invention. A laminate polishing pad 1 according to the invention has a structure including a polishing layer 8 with no region passing therethrough and a cushion layer 10, which are laminated with an adhesive layer 9a interposed therebetween. The adhesive layer 9a has at least one non-adhering region Y (13) continuously extending from a central region of the adhesive layer 9a to a peripheral end of the adhesive layer 9a. In this mode, therefore, the non-adhering region X (11) formed in the polishing layer 8 is replaced by the non-adhering region Y (13) formed in the adhesive layer 9a. In another mode, the polishing layer 8 may have the non-adhering region X (11), and at the same time, the adhesive layer 9a may have the non-adhering region Y (13). In such a case, the non-adhering region X (11) and the non-adhering region Y (13) may or may not overlap in the direction of the thickness.

The non-adhering region Y (13) may have any shape as long as it is at least formed continuously from the central region to the peripheral end of the adhesive layer 9a. The same shape as that of the non-adhering region X (11) may be used for the non-adhering region Y (13). When the adhesive layer 9a is circular, the central region may be a 3 cm radius region from the center, and when the adhesive layer 9a has an elongated shape, the central region may be a region from the center to the left and right edges each 3 cm apart in the width direction.

The non-adhering region Y (13) may be a groove or grooves passing through or not passing through the adhesive layer 9a. The width of the groove, which may be adjusted as needed depending on the size of the adhesive layer 9a, is generally from about 0.1 to about 10 mm, preferably from 0.5 to 3 mm. The depth of the non-through groove, which may be adjusted as needed depending on the thickness of the adhesive layer 9a, is generally from about 10 to about 100 μm, preferably from 20 to 70 μm.

Examples of the method of forming the non-adhering region Y (13) include, but are not limited to, a method including stacking two or more adhesive layers and partially or entirely removing a specific part of the adhesive layer(s) by cutting with an edge tool, a method of pressing resin with a pressing plate having a specific surface pattern to form the region, and a method of performing decomposition and removal using a beam from a laser such as a carbon dioxide laser to form the region.

The total surface area of the non-adhering region Y (13) is preferably from 0.1 to 30%, more preferably from 0.5 to 10% of the surface area of the adhesive layer 9a.

The material used to form the adhesive layer 9a and the thickness of the adhesive layer 9a may be the same as those described above. The method of bonding the polishing layer and the cushion layer together may also be the same as described above.

On the other hand, FIG. 11 is a schematic cross-sectional view showing another structure of the laminate polishing pad of the invention. A laminate polishing pad 1 according to the invention has a structure including a polishing layer 8 with no region passing therethrough and a cushion layer 10, which are laminated with an adhesive member 9 interposed therebetween. The adhesive member 9, which includes a base film 9b and adhesive layers 9a provided on both sides of the base film 9b, is a product usually called double-sided adhesive tape. The adhesive layer 9a placed on the polishing layer side of the base film 9b has at least one non-adhering region Y (13) continuously extending from a central region of the adhesive layer 9a to a peripheral end of the adhesive layer 9a. In this mode, therefore, the non-adhering region Y (13) formed in the adhesive layer 9a shown in FIG. 10 is replaced by the non-adhering region Y (13) formed in the adhesive layer 9a located on the polishing layer side of the double-sided adhesive tape. In another mode, the polishing layer 8 may have the non-adhering region X (11), and at the same time, the adhesive layer 9a located on the polishing layer side of the double-sided adhesive tape may have the non-adhering region Y (13). The details of the non-adhering region, the material used to form it, and the method of forming it may be the same as those described above.

Means for adhering the polishing layer to the cushion layer include: for example, a method in which a double-sided adhesive tape is sandwiched between the polishing layer and the cushion layer, followed by pressing.

In the laminate polishing pad of the invention, an adhesive layer or a double-sided adhesive tape for adhering to a platen may also be provided on the other side of the cushion layer. The double-sided adhesive tape to be used may have a general structure including a base film and adhesive layers provided on both sides of the film as stated above.

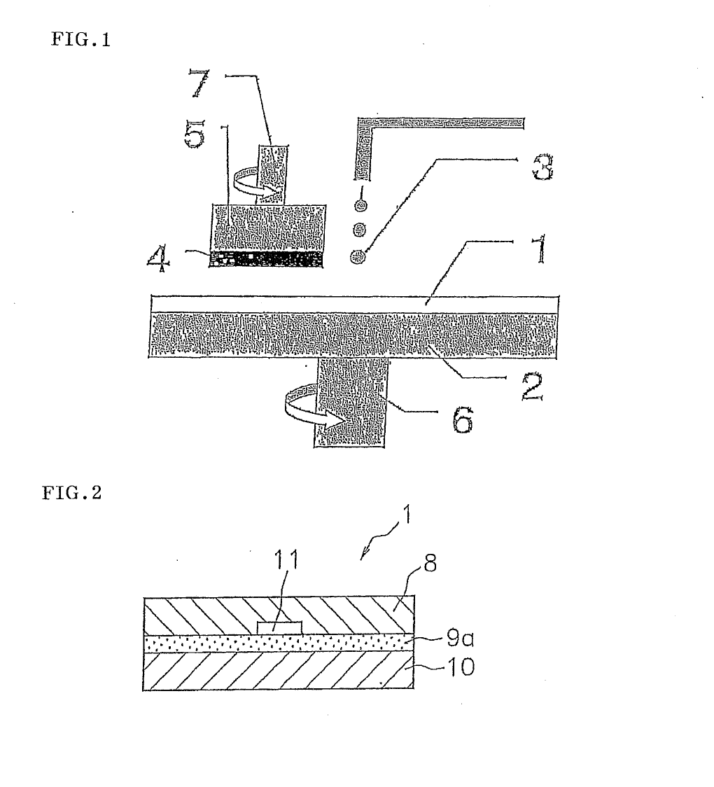

A semiconductor device is fabricated after operation in a step of polishing a surface of a semiconductor wafer with a laminate polishing pad. The term, a semiconductor wafer, generally means a silicon wafer on which a wiring metal and an oxide layer are stacked. No specific limitation is imposed on a polishing method of a semiconductor wafer or a polishing apparatus, and polishing is performed with a polishing apparatus equipped, as shown in FIG. 1, with a polishing platen 2 supporting a laminate polishing pad 1, a polishing head 5 holding a semiconductor wafer 4, a backing material for applying a uniform pressure against the wafer and a supply mechanism of a polishing agent 3. The laminate polishing pad 1 is mounted on the polishing platen 2 by adhering the pad to the platen with a double-sided adhesive tape. The polishing platen 2 and the polishing head 5 are disposed so that the laminate polishing pad 1 and the semiconductor wafer 4 supported or held by them oppositely face each other and provided with respective rotary shafts 6 and 7. A pressure mechanism for pressing the semiconductor wafer 4 to the laminate polishing pad 1 is installed on the polishing head 5 side. During polishing, the semiconductor wafer 4 is polished by being pressed against the laminate polishing pad 1 while the polishing platen 2 and the polishing head 5 are rotated and a slurry is fed. No specific limitation is placed on a flow rate of the slurry, a polishing load, a polishing platen rotation number and a wafer rotation number, which are properly adjusted.

Protrusions on the surface of the semiconductor wafer 4 are thereby removed and polished flatly. Thereafter, a semiconductor device is produced therefrom through dicing, bonding, packaging etc. The semiconductor device is used in an arithmetic processor, a memory etc.

### EXAMPLES

Description will be given of the invention with examples, while the invention is not limited to description in the examples.

### [Methods for Measurement and Evaluation]

### (Measurement of Number Average Molecular Weight)

The number average molecular weight was measured as a polystyrene-equivalent value by GPC (gel permeation chromatography) with standard polystyrene.

GPC system: LC-10A manufactured by Shimadzu Corporation
Columns: three columns PLgel (5 μm, 500 Å), PLgel (5 μm, 100 Å) and PLgel (5 μm, 50 Å) each manufactured by Polymer Laboratories were coupled and used.
Flow rate: 1.0 ml/minute

### Concentration: 1.0 g/1

Injection volume: 40 μl
Column temperature: 40° C.
Eluent: tetrahydrofuran

### (Measurement of Average Cell Diameter)

A manufactured polyurethane foam was sliced with a microtome cutter into measurement samples each with the thinnest possible thickness of 1 mm or less. A surface of a sample was photographed with a scanning electron microscope (manufactured by Hitachi Science System Co. with a model number of S-3500N) at a magnification of ×100. An effective circular diameter of each of all cells in an arbitrary area was measured with an image analyzing soft (manufactured by MITANI Corp. with a trade name WIN-ROOF) and an average cell diameter was calculated from the measured values.

### (Measurement of Specific Gravity)

Determined according to JIS Z8807-1976. A manufactured polyurethane foam cut out in the form of a strip of 4 cm×8.5 cm (thickness: arbitrary) was used as a sample for measurement of specific gravity and left for 16 hours in an environment of a temperature of 23±2° C. and a humidity of 50%±5%. Measurement was conducted by using a specific gravity hydrometer (manufactured by Sartorius Co., Ltd).

### (Measurement of Hardness)

Measurement is conducted according to JIS K6253-1997. A manufactured polyurethane foam cut out in a size of 2 cm×2 cm (thickness: arbitrary) was used as a sample for measurement of hardness and left for 16 hours in an environment of a temperature of 23±2° C. and a humidity of 50%±5%. At the time of measurement, samples were stuck on one another to a thickness of 6 mm or more. A hardness meter (Asker D hardness meter, manufactured by Kobunshi Keiki Co., Ltd.) was used to measure hardness.

### (Evaluation of Gas Blistering or Internal Peeling)

A 10,000-Å thick tungsten wafer was polished for 30 hours under the conditions described below, using the prepared laminate polishing pad, and subsequently, visual observation of the laminate polishing pad was made to determine whether or not gas blistering or internal peeling occurred between the layers. The polishing apparatus used was SPP600S (manufactured by Okamoto Machine Tool Works, Ltd.). The polishing conditions were as follows. The slurry used was an aqueous solution obtained by a process including diluting W2000 (manufactured by Cabot Corporation) 2 times with ultrapure water and adding 2% by weight of hydrogen peroxide water to the dilution. The aqueous solution was added at a flow rate of 150 ml/minute during the polishing. The polishing load, the number of polishing platen revolutions, and the number of wafer revolutions were 5 psi, 120 rpm, and 120 rpm, respectively. Using a dresser (Type M100, manufactured by Asahi Diamond Industrial Co., Ltd.), the surface of the polishing layer was dressed for 20 seconds at predetermined intervals under the conditions of a dressing load of 50 g/cm², a number of dresser revolutions of 15 rpm, and a number of platen revolutions of 30 rpm.

### (Peel Strength and Peel Strength Retention)

Three samples each with a width of 25 mm and a length of 40 mm (not containing any non-adhering region) were cut out of the prepared laminate polishing pad. The peel strengths (N/25 mm) of the three samples were measured respectively under the conditions of a peel angle of 180° and a peel rate of 50 mm/minute using a tensile tester (AUTOGRAPH AG-X, manufactured by SHIMADZU CORPORATION), and the average value was calculated. After the polishing process was performed as described above, three samples each with a width of 25 mm and a length of 40 mm (not containing any non-adhering region) were also cut out of the laminate polishing pad. The average of the peel strengths was determined by the same method. It is preferred that after the polishing process, the laminate polishing pad should have a peel strength of 10 N/25 mm or more. The peel strength retention was also calculated from the average peel strengths before and after the polishing process.

The peel strength retention=(the average peel strength after the polishing process/the average peel strength before the polishing process)×100

### Production Example 1

### Production of Polishing Layer

To a polymerization vessel were added 100 parts by weight of an isocyanate-terminated prepolymer (ADIPRENE L-325, manufactured by Chemtura Corporation) and 3 parts by weight of a silicone surfactant (SH-192, manufactured by Dow Corning Toray Silicone Co., Ltd.) and mixed. The mixture was adjusted to 80° C. and degassed under reduced pressure. Subsequently, the mixture was vigorously stirred with a stirring blade at a number of revolutions of 900 rpm for about 4 minutes in such a manner that air bubbles were incorporated into the reaction system. To the resulting mixture was added 26 parts by weight of 4,4′-methylenebis (o-chloroaniline) (IHARACUAMINE-MT, manufactured by IHARA CHEMICAL INDUSTRY CO., LTD.), which had been previously melted at 120°. The liquid mixture was stirred for about 1 minute and then poured into a loaf-shaped open mold (casting vessel). At the point when the liquid mixture lost its fluidity, it was placed in an oven, and subjected to post curing at 100° C. for 16 hours, so that a polyurethane foam block was obtained.

While heated at 80° C., the polyurethane foam block was sliced using a slicer (VGW-125, manufactured by AMITEC Corporation), so that a polyurethane foam sheet was obtained (50 μm in average cell size, 0.86 in specific gravity, 52 degrees in hardness). Subsequently, the surface of the sheet was buffed using a buffing machine (manufactured by AMITEC Corporation) until its thickness reached 1.27 mm, so that a sheet with regulated thickness accuracy was obtained. The buffing was performed using first a belt sander with 120-mesh abrasive grains (manufactured by RIKEN CORUNDUM CO., LTD.), then a belt sander with 240-mesh abrasive grains (manufactured by RIKEN CORUNDUM CO., LTD.), and finally a belt sander with 400-mesh abrasive grains (manufactured by RIKEN CORUNDUM CO., LTD.) for finishing. The buffed sheet was stamped into a piece with a diameter of 60 cm. Concentric circular grooves with a width of 0.25 mm, a pitch of 1.5 mm, and a depth of 0.6 mm were formed on the polishing surface of the piece using a grooving machine (manufactured by Techno Corporation), so that a polishing layer was obtained.

### Example 1

Using a grooving machine (manufactured by Techno Corporation), grooves with a width of 1.0 mm and a depth of 0.1 mm were radially formed as the non-adhering region X on the back surface of the polishing layer, which was prepared in Production Example 1, at angle intervals of 45° from the center to the peripheral end. The total surface area of the non-adhering region X was 0.84% of the surface area of the polishing layer. Subsequently, a 60-cm diameter double-sided adhesive tape (base film: a 25-μm thick PET film, adhesive layers: 50-μm thick acrylic adhesive layers) was bonded to the back surface of the polishing layer using a laminating machine. A 60-cm diameter cushion layer (a polyurethane foam with a thickness of 0.8 mm) was then bonded to the other side of the double-sided adhesive tape, so that a laminate polishing pad was obtained.

### Example 2

Using a grooving machine (manufactured by Techno Corporation), grooves with a width of 1.0 mm and a depth of 0.1 mm were radially formed as the non-adhering region X on the back surface of the polishing layer, which was prepared in Production Example 1, at angle intervals of 45° from the center to the peripheral end. In addition, a concentric groove with a width of 0.25 mm and a depth of 0.1 mm was formed as the non-adhering region X at a position 100 mm apart from the center in the radial direction. The total surface area of the non-adhering region X was 0.91% of the surface area of the polishing layer. Subsequently, a laminate polishing pad was prepared by the same method as in Example 1.

### Example 3

Radial parts with a width of 1.0 mm extending from the center to the peripheral end were removed at angle intervals of 45° from the adhesive layer of a 60-cm diameter double-sided adhesive tape (base film: a 25-μm thick PET film, adhesive layers: 50-μm thick acrylic adhesive layers), in which the adhesive layer was on the side to be bonded to the polishing layer, so that the non-adhering region Y was formed. The total surface area of the non-adhering region Y was 0.84% of the surface area of the adhesive layer. Subsequently, using a laminating machine, the non-adhering region Y-containing adhesive layer of the double-sided adhesive tape was bonded to the back surface of the polishing layer prepared in Production Example 1. A 60-cm diameter cushion layer (a polyurethane foam with a thickness of 0.8 mm) was then bonded to the other side of the double-sided adhesive tape, so that a laminate polishing pad was obtained.

### Example 4

Using a grooving machine (manufactured by Techno Corporation), grooves with a width of 2.0 mm, a depth of 0.13 mm, and a pitch of 45 mm were formed as the non-adhering region X in a lattice pattern as shown in FIG. 8 on the back surface of the polishing layer prepared in Production Example 1. The total surface area of the non-adhering region X was 8.3% of the surface area of the polishing layer. Subsequently, using a laminating machine, a 60-cm diameter adhesive layer (a 130-μm thick acrylic adhesive layer) was bonded to the back surface of the polishing layer. A 60-cm diameter cushion layer (a polyurethane foam with a thickness of 0.8 mm) was then bonded to the other side of the adhesive layer, so that a laminate polishing pad was obtained.

### Example 5

Using a grooving machine (manufactured by Techno Corporation), grooves with a width of 2.0 mm, a depth of 0.13 mm, and a pitch of 45 mm were formed as the non-adhering region X in a lattice pattern as shown in FIG. 8 on the back surface of the polishing layer prepared in Production Example 1. The total surface area of the non-adhering region X was 8.3% of the surface area of the polishing layer. In addition, a 2.0-mm wide part from one end to the other through the center was removed from the adhesive layer of a 60-cm diameter double-sided adhesive tape (base film: a 25-μm thick PET film, adhesive layers: 50-μm thick acrylic adhesive layers), in which the adhesive layer was on the side to be bonded to the polishing layer, so that the non-adhering region Y was formed. Subsequently, using a laminating machine, the double-sided adhesive tape was bonded to the back surface of the polishing layer in such a manner that the non-adhering region X and non-adhering region Y overlapped each other. A 60-cm diameter cushion layer (a polyurethane foam with a thickness of 0.8 mm) was then bonded to the other side of the double-sided adhesive tape, so that a laminate polishing pad was obtained.

### Example 6

Using a grooving machine (manufactured by Techno Corporation), grooves with a width of 1.0 mm and a depth of 0.1 mm were radially formed as the non-adhering region X on the back surface of the polishing layer, which was prepared in Production Example 1, at angle intervals of 45° from the center to the peripheral end. The total surface area of the non-adhering region X was 0.84% of the surface area of the polishing layer. Using a laminating machine, a 60-cm diameter urethane-based hot melt adhesive sheet (UH-203 manufactured by Nihon Matai Co., Ltd., 75 μm in thickness) and a 60-cm diameter cushion layer (a polyurethane foam with a thickness of 0.8 mm) were stacked on the back surface of the polishing layer. The urethane-based hot melt adhesive sheet was melted by heating so that the polishing layer and the cushion layer was bonded together to form a laminate polishing pad.

### Example 7

Using a grooving machine (manufactured by Techno Corporation), grooves with a width of 1.0 mm and a depth of 0.1 mm were radially formed as the non-adhering region X on the back surface of the polishing layer, which was prepared in Production Example 1, at angle intervals of 45° from the center to the peripheral end. The total surface area of the non-adhering region X was 0.84% of the surface area of the polishing layer. Using a laminating machine, a 60-cm diameter urethane-based hot melt adhesive sheet (UH-203 manufactured by Nihon Matai Co., Ltd., 75 μm in thickness) and a 60-cm diameter, corona-treated PET film (50 μm in thickness) were stacked on the back surface of the polishing layer. The urethane-based hot melt adhesive sheet was melted by heating so that the polishing layer and the PET film was bonded together to form a laminate sheet. Subsequently, using a laminating machine, a 60-cm diameter urethane-based hot melt adhesive sheet (UH-203 manufactured by Nihon Matai Co., Ltd., 75 μm in thickness) and a 60-cm diameter cushion layer (a polyurethane foam with a thickness of 0.8 mm) were stacked on the PET film side of the laminate sheet, and the urethane-based hot melt adhesive sheet was melted by heating so that the laminate sheet and the cushion layer was bonded together to form a laminate polishing pad.

### Comparative Example 1

Using a laminating machine, a 60-cm diameter double-sided adhesive tape (base film: a 25-μm thick PET film, adhesive layers: 50-μm thick acrylic adhesive layers) was bonded to the back surface of the polishing layer prepared in Production Example 1. A 60-cm diameter cushion layer (a polyurethane foam with a thickness of 0.8 mm) was then bonded to the other side of the double-sided adhesive tape, so that a laminate polishing pad was obtained.

TABLE 1

| | | | Initial | Peel | |
|---|---|---|---|---|---|
| | | | peel | strength | |
| | | | strength | after | |
| | Gas | Internal | (N/25 | polishing | Retention |
| | blistering | peeling | mm) | (N/25 mm) | (%) |
| Example 1 | Absent | Absent | 24.2 | 22.5 | 93 |
| Example 2 | Absent | Absent | 24.1 | 21.9 | 91 |
| Example 3 | Absent | Absent | 24.1 | 23.1 | 96 |
| Example 4 | Absent | Absent | 23.9 | 22.3 | 93 |
| Example 5 | Absent | Absent | 23.7 | 22.5 | 95 |
| Example 6 | Absent | Absent | 43.1 | 41.5 | 96 |
| Example 7 | Absent | Absent | 44.8 | 43.5 | 97 |
| Comparative | Present | Present | 23.8 | 7.6 | 32 |
| Example 1 | | | | | |

Table 1 shows that gas blistering or internal peeling did not occur between the layers of the laminate polishing pad of each of Examples 1 to 7 even after polishing with it for a long time, because it had the non-adhering region X and/or the non-adhering region Y. In contrast, gas blistering and internal peeling occurred between the layers of the laminate polishing pad of Comparative Example 1, because it had neither the non-adhering region X nor the non-adhering region Y.

A laminate polishing pad of the invention is capable of performing planarization materials requiring a high surface planarity such as optical materials including a lens and a reflective mirror, a silicon wafer, a glass substrate or an aluminum substrate for a hard disk and a product of general metal polishing with stability and a high polishing efficiency. A laminate polishing pad of the invention is preferably employed, especially, in a planarization step of a silicon wafer or a device on which an oxide layer or a metal layer has been formed prior to further stacking an oxide layer or a metal layer thereon.

In the drawings, reference numeral 1 represents a laminate polishing pad, 2 a polishing platen, 3 a polishing agent (slurry), 4 an object to be polished (semiconductor wafer), 5 a support (polishing head), 6 and 7 each a rotating shaft, 8 a polishing layer, 9 an adhesive member (adhesive layer, double-sided adhesive tape), 9a an adhesive member, 9b a base film, 10 a cushion layer, 11a non-adhering region X, 12 a central region, and 13 a non-adhering region Y.

1. A laminate polishing pad, comprising:
a polishing layer with no region passing therethrough;
an adhesive member; and
a cushion layer placed on the polishing layer with the adhesive member interposed therebetween, wherein
a back side of the polishing layer has at least one non-adhering region X continuously extending from a central region of the polishing layer to a peripheral end of the polishing layer, and/or
the adhesive member has at least one non-adhering region Y continuously extending from a central region of the adhesive member to a peripheral end of the adhesive member.

2. The laminate polishing pad according to claim 1, wherein the adhesive member comprises a base film and adhesive layers provided on both sides of the base film, and the adhesive layer on the polishing layer side has the non-adhering region Y.

3. The laminate polishing pad according to claim 1, wherein the non-adhering region X or Y is formed radially or in a lattice pattern.

4. The laminate polishing pad according to claim 1, wherein the non-adhering region X or Y has a total surface area equal to 0.1 to 30% of the surface area of the polishing layer.

5. A method for manufacturing a semiconductor device, comprising the step of polishing a surface of a semiconductor wafer using the laminate polishing pad according to claim 1.
